(19) United States
(12) Patent Application Publication
(10) Pub. No.: US 2026/0078049 A1
(43) Pub. Date: Mar. 19, 2026

(54) GLASS SUBSTRATE PROCESSING METHOD, AND ELECTRONIC DEVICE MANUFACTURING METHOD

(71) Applicant: Gigaphoton Inc., Oyama-shi (JP)

(72) Inventors: Yasufumi KAWASUJI, Oyama-shi (JP); Takashi SAITO, Oyama-shi (JP)

(73) Assignee: Gigaphoton Inc., Oyama-shi (JP)

(21) Appl. No.: 19/288,345

(22) Filed: Aug. 1, 2025

(30) Foreign Application Priority Data
Sep. 18, 2024 (JP) 2024-161167

(51) Int. Cl. C03C 15/00; H01L 21/48

(52) U.S. Cl. CPC C03C 15/00; H10W 70/095

(57) ABSTRACT

A glass substrate processing method includes forming a through hole by irradiating a glass substrate with ultraviolet-wavelength pulse laser light; forming a modified section by irradiating a region surrounding the through hole with ultrashort pulse laser light, the region extending over a predetermined range from an inner wall of the through hole; and etching the glass substrate with an etchant to increase a hole diameter of the through hole, the etchant providing an etching rate for etching the modified section higher than an etching rate for etching the glass substrate excluding the modified section.

### CROSS-REFERENCE TO RELATED APPLICATIONS

The present application claims the benefit of Japanese Patent Application No. 2024-161167, filed on Sep. 18, 2024, the entire contents of which are hereby incorporated by reference.

### BACKGROUND

### 1. Technical Field

The present disclosure relates to a glass substrate processing method, and an electronic device manufacturing method.

### 2. Related Art

In recent years, a semiconductor exposure apparatus is required to improve the resolution thereof as semiconductor integrated circuits are increasingly miniaturized and highly integrated. To this end, reduction in the wavelength of light emitted from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The excimer laser light, which has a pulse width of about several tens of nanoseconds and has a short wavelength of 248 nm or 193 nm, may further be used to directly process a polymer material, a glass material, and other materials. The excimer laser light having photon energy higher than the chemical binding energy of a polymer material can unbind the chemical bond in the polymer material. Non-thermal processing can therefore be performed on a polymer material by using excimer laser light, and it is known that an excellent processed shape is achieved by the non-thermal processing. Glass, ceramic, and other materials absorb excimer laser light by a large amount, and it is therefore known that excimer laser light can process such a material difficult to process with visible or infrared laser light.

### CITATION LIST

### Patent Literature

[PTL 1] JP-A-2000-302488
[PTL 2] JP-A-2004-351494

### SUMMARY

A glass substrate processing method according to an aspect of the present disclosure may include forming a through hole by irradiating a glass substrate with ultraviolet-wavelength pulse laser light; forming a modified section by irradiating a region surrounding the through hole with ultrashort pulse laser light, the region extending over a predetermined range from an inner wall of the through hole; and etching the glass substrate with an etchant to increase a hole diameter of the through hole, the etchant providing an etching rate for etching the modified section higher than an etching rate for etching the glass substrate excluding the modified section.

A glass substrate processing method according to another aspect of the present disclosure may include forming a modified section by irradiating a glass substrate with ultrashort pulse laser light, forming a through hole surrounded by the modified section by irradiating the glass substrate with ultraviolet-wavelength pulse laser light; and etching the glass substrate with an etchant to increase a hole diameter of the through hole, the etchant providing an etching rate for etching the modified section higher than an etching rate for etching the glass substrate excluding the modified section.

An electronic device manufacturing method according to another aspect of the present disclosure may include forming a through hole by irradiating a glass substrate with ultraviolet-wavelength pulse laser light; forming a modified section by irradiating a region surrounding the through hole with ultrashort pulse laser light, the region extending over a predetermined range from an inner wall of the through hole; etching the glass substrate with an etchant to increase a hole diameter of the through hole, the etchant providing an etching rate for etching the modified section higher than an etching rate for etching the glass substrate excluding the modified section, to produce an interposer substrate; placing an electric conductor in the through hole having the increased hole diameter in the interposer substrate, and electrically connecting two principal surfaces of the interposer substrate to each other via the electric conductor; coupling the interposer substrate and an integrated circuit chip to each other to electrically connect the interposer substrate and the integrated circuit chip to each other; and coupling the interposer substrate and a circuit substrate to each other to electrically connect the interposer substrate and the circuit substrate to each other.

### BRIEF DESCRIPTION OF DRAWINGS

Embodiments of the present disclosure will be presented below only by way of example with reference to the accompanying drawings.

FIG. 1 is a diagrammatic view showing an example of a schematic configuration of the entirety of a laser processing system according to Comparative Example.

FIG. 2 is a flowchart showing the procedure of a glass substrate processing method according to Comparative Example.

FIG. 3 shows that a glass substrate is irradiated with ultrashort pulse laser light.

FIG. 4 shows a glass substrate in which a modified section has been formed.

FIG. 5 shows an etching step of forming a through hole in the glass substrate.

FIG. 6 shows the through hole formed by the glass substrate processing method according to Comparative Example.

FIG. 7 is a diagrammatic view showing an example of a schematic configuration of the entirety of a laser processing system according to a first embodiment.

FIG. 8 is a flowchart showing the procedure of a glass substrate processing method according to the first embodiment.

FIG. 9 shows that a glass substrate is irradiated with ultraviolet-wavelength pulse laser light.

FIG. 10 shows the glass substrate in which a through hole has been formed.

FIG. 11 shows that a region extending over a predetermined range from the inner wall of the through hole is irradiated with ultrashort pulse laser light.

FIG. 12 shows the glass substrate in which a modified section is formed in the region extending over the predetermined range from the inner wall of the through hole.

FIG. 13 shows an etching step of increasing the hole diameter of the through hole in the first embodiment.

FIG. 14 shows the result of the process performed by using the glass substrate processing method according to the first embodiment.

FIG. 15 is a flowchart showing the procedure of a glass substrate processing method according to a second embodiment.

FIG. 16 shows that a modified section formed in a glass substrate is irradiated with ultraviolet-wavelength pulse laser light.

FIG. 17 diagrammatically shows the configuration of an electronic device.

FIG. 18 is a flowchart showing the procedure of an electronic device manufacturing method according to a third embodiment.

FIG. 19 diagrammatically shows a wiring formation step of placing electric conductors in through holes in an interposer substrate.

### DETAILED DESCRIPTION

1. Description of laser processing system and glass substrate processing method according to Comparative Example
   1.1 Configuration of laser processing system
   1.2 Description of glass substrate processing method

### 1.3 Problems

2. Description of laser processing system and glass substrate processing method according to first embodiment
2.1 Configuration of laser processing system
2.2 Description of glass substrate processing method
2.3 Effects and advantages
3. Description of laser processing system and glass substrate processing method according to second embodiment
3.1 Configuration of laser processing system
3.2 Description of glass substrate processing method
3.3 Effects and advantages
4. Description of electronic device manufacturing method according to third embodiment

### 4.1 Configuration

4.2 Description of electronic device manufacturing method

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same elements have the same reference characters, and no redundant description of the same elements will be made.

### 1. Description of Laser Processing System and Glass Substrate Processing Method According to Comparative Example

### 1.1 Configuration of Laser Processing System

The configuration of a laser processing system according to Comparative Example will be described. Comparative Example of the present disclosure is a form that the applicant is aware of as known only by the applicant, and is not a publicly known example that the applicant is self-aware of.

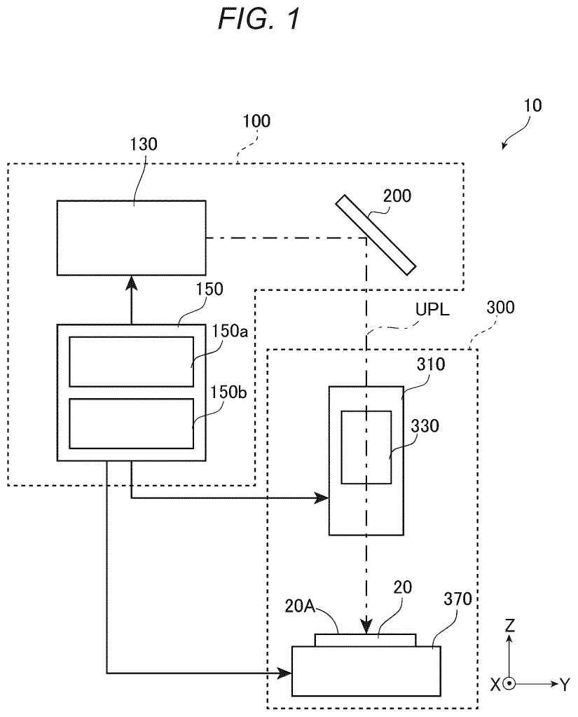

FIG. 1 is a diagrammatic view showing an example of a schematic configuration of the entirety of a laser processing system 10, which forms a through hole in a glass substrate. In Comparative Example of the present disclosure, the laser processing system 10 includes a laser light apparatus 100 and a laser processing apparatus 300 as primary configurations. The description below will be made under the following definitions: A direction parallel to the direction of the optical axis of laser light incident on a glass substrate 20, which is a workpiece, is a Z direction; a direction perpendicular to the Z direction is an X direction; and a direction perpendicular to the X and Z directions is a Y direction.

The laser light apparatus 100 includes an ultrashort pulse laser light source 130, a processor 150, and a highly reflective mirror 200 as primary configurations.

The ultrashort pulse laser light source 130 outputs pulse laser light having a 1-μm band. The 1-μm band is, for example, a wavelength region from 0.9 μm to 1.1 μm. The ultrashort pulse laser light source 130 is, for example, a system that is a YAG (yttrium aluminum garnet) laser light apparatus that outputs laser light having a center wavelength of about 1.06 μm combined with a pulse compressing optical unit or the like. The pulse width of ultrashort pulse laser light UPL is, for example, 1 nanosecond or smaller. The pulse width may fall within the picosecond or femtosecond region.

The processor 150 in the present disclosure is a processing device including a storage 150a, which stores a control program, and a CPU (central processing unit) 150b, which executes the control program. The processor 150 is particularly configured or programmed to carry out various processes included in the present disclosure. The processor 150 controls the entire laser processing system 10. The processor 150 is electrically connected to the laser light apparatus 100 and the laser processing apparatus 300, and controls the entire laser processing system 10.

The highly reflective mirror 200 is fixed to a holder that is not shown. The highly reflective mirror 200 is configured, for example, with a dielectric multilayer film including a transparent substrate made of synthetic quartz or calcium fluoride having a surface at which a film made of a dielectric material, such as titanium oxide (TiO₂) or silicon oxide (SiO₂), is formed so that the surface reflects the ultrashort pulse laser light UPL at high reflectance. The highly reflective mirror 200 reflects the laser light incident from the ultrashort pulse laser light source 130 to the laser processing apparatus 300.

The laser processing apparatus 300 includes a radiation optical system 310 and a stage 370 as primary configurations.

The radiation optical system 310 guides the ultrashort pulse laser light UPL output from the laser light apparatus 100 to the glass substrate 20, and then, in Comparative Example of the present disclosure, to one surface 20A of the glass substrate 20 at right angles, which is the side on which the ultrashort pulse laser light UPL is incident. The radiation optical system 310 moves, in the in-plane direction of the surface 20A, the position at which the ultrashort pulse laser light UPL is radiated. The radiation optical system 310 further includes a focus position adjuster 330, which adjusts the position where the ultrashort pulse laser light UPL is brought into focus in such a way that the focus position moves in the thickness direction of the glass substrate 20. The focus position adjuster 330 includes, for example, a diffractive optical element and a refractive focusing lens none of which is shown.

The stage 370 can move the glass substrate 20 in the X, Y, and Z directions in accordance with a control signal from the processor 150. The stage 370 supports the glass substrate 20. The stage 370 can adjust the position of the glass substrate 20 in such a way that a desired position on the glass substrate 20 is irradiated with the ultrashort pulse laser light UPL output from the laser light apparatus 100.

The glass substrate 20 is a target object on which laser processing is performed by the radiated ultrashort pulse laser light UPL. The thickness of the glass substrate 20 is, for example, greater than or equal to 100 μm but smaller than or equal to 2000 μm. The material of the glass substrate 20 may, for example, be alkali-free glass.

### 1.2 Description of Glass Substrate Processing Method

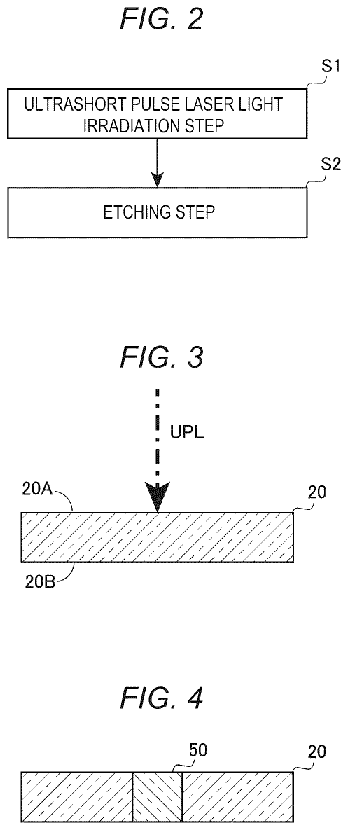

A glass substrate processing method according to Comparative Example will next be described with reference to FIGS. 2 to 6.

FIG. 2 is a flowchart showing the procedure of the glass substrate processing method according to Comparative Example of the present disclosure. The glass substrate processing method according to Comparative Example of the present disclosure includes steps S1 and S2, as shown in FIG. 2.

### <Step S1>

This step is the step of irradiating the glass substrate 20 with the ultrashort pulse laser light UPL. FIG. 3 shows that the glass substrate 20 is irradiated with the ultrashort pulse laser light UPL. In this step, the processor 150 controls the stage 370 to set the coordinates X and Y of the position where the ultrashort pulse laser light UPL is radiated, and controls the laser light apparatus 100 to cause it to irradiate a desired position on the glass substrate 20 with the ultrashort pulse laser light UPL, as shown in FIG. 3.

The processor 150 controls the radiation optical system 310 to bring the ultrashort pulse laser light UPL into focus at a desired position in the glass substrate 20 in the thickness direction. In Comparative Example of the present disclosure, the processor 150 controls the focus position adjuster 330 to move the position where the ultrashort pulse laser light UPL is brought into focus in the thickness direction of the glass substrate 20, for example, from the one surface 20A to the other surface 20B, which is opposite to the one surface 20A, so that a modified section 50 grows in the thickness direction. FIG. 4 shows the glass substrate 20 in which the modified section 50 is formed. In the portion at which the ultrashort pulse laser light UPL is brought into focus and which is irradiated by the focused ultrashort pulse laser light UPL, the material is modified as shown in FIG. 4, and a cylindrical modified section 50 is formed. The outer diameter of the modified section 50 is greater than or equal to 20 μm but smaller than or equal to 200 μm in Comparative Example of the present disclosure, but the outer diameter of the modified section 50 may be smaller than 20 μm or greater than 200 μm. After this step, step S2 is executed.

### <Step S2>

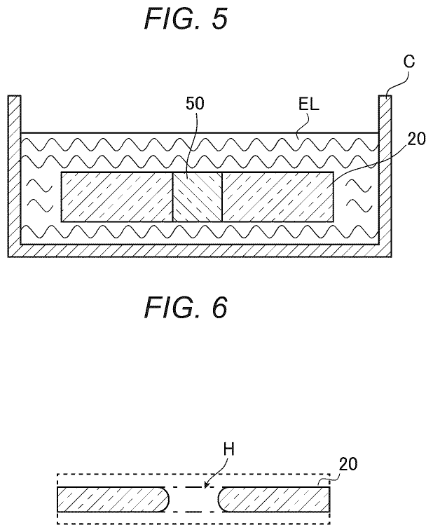

This step is the step of etching the glass substrate 20 to form a through hole H. FIG. 5 shows an etching step of forming the through hole H in the glass substrate 20. In this step, the glass substrate 20 is immersed in an etchant EL stored in a container C, as shown in FIG. 5. The etchant El is an etchant providing an etching rate for etching the modified section 50 formed in step S1 higher than an etching rate for etching the glass substrate 20 excluding the modified section 50. Examples of the etchant EL may include hydrofluoric acid, KOH, and other strong alkaline solutions. The modified section 50 is quickly etched, so that the through hole H can be formed in the glass substrate 20.

### 1.3 Problems

Let ESD be the etching rate at which the modified section 50 described above is etched, ESN be the etching rate at which the glass substrate 20 excluding the modified section 50 is etched, R be ESD/ESN, which is the etching rate ratio of the etching rate ESD to the etching rate ESN, and T be the plate thickness of the pre-processed glass substrate 20 to be etched, the amount of etching EC₀ required to form a through hole H having a hole diameter d1 is expressed by Expression (1) below.

$${EC}_{0} = ( 1 / 2 ) \times T \qquad ( 1 )$$

The amount of reduction EL₀ in the plate thickness in the case of the amount of etching EC₀ is expressed by Expression (2) below.

$${EL}_{0} = 2 \times ( 1 / R ) \times {EC}_{0} \qquad ( 2 )$$

For example, it is assumed that the plate thickness is 1000 μm, and that the etching rate at which the modified section 50 is etched is four times the etching rate at which the glass substrate 20 excluding the modified section 50 is etched. In this case, according to Expressions (1) and (2), the amount of etching EC₀ is 500 μm, and the amount of reduction EL₀ in the plate thickness is 250 μm regardless of the size of the hole diameter d1. That is, according to the glass substrate processing method shown in Comparative Example, one quarter of the glass substrate 20 is lost, which means that a large amount of the material is lost.

FIG. 6 shows the through hole H formed by the glass substrate processing method according to Comparative Example. In FIG. 6, the dotted line indicates the glass substrate 20 before the processing. A substantial portion of the glass substrate 20 is lost by the etching for forming the through hole H, as shown in FIG. 6.

Note that the glass substrate processing method according to Comparative Example of the present disclosure, in which the glass substrate 20 is etched from both the one surface 20A and the other surface 20B, causes the hole diameter of the near-entrance opening of the formed through hole H to be greater than the hole diameter at an inner central portion of the glass substrate 20. The inner wall of the formed through hole H is therefore curved, and the hole does not have a cylindrical shape, as shown in FIG. 6.

The following embodiments therefore show, by way of example, a glass substrate processing method that allows formation of the through hole H with an increase in material loss suppressed, and an electronic device manufacturing method using an interposer processed by the processing method.

### 2. Description of Laser Processing System and Glass Substrate Processing Method According to First Embodiment

The laser processing system according to a first embodiment will next be described. Note that the same configurations as those described above have the same reference characters, and duplicate description of the same configurations will be omitted unless otherwise particularly described.

### 2.1 Configuration of Laser Processing System

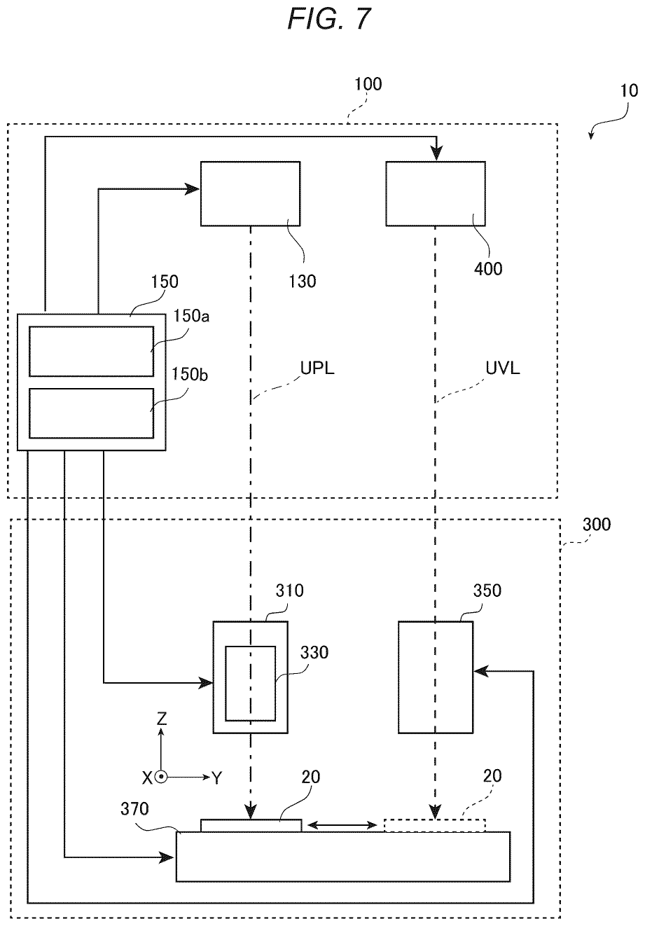

FIG. 7 is a diagrammatic view showing an example of a schematic configuration of the entirety of the laser processing system 10 according to the present embodiment. The laser processing system 10 according to the present embodiment differs from the laser processing system 10 according to Comparative Example in that the laser light apparatus 100 includes an ultraviolet-wavelength pulse laser light source 400, and that the laser processing apparatus 300 includes a radiation optical system 350, which brings ultraviolet-wavelength pulse laser light UVL into focus. The stage 370 is configured to be capable of moving the glass substrate 20 in such a way that a desired position on the glass substrate 20 is irradiated with the ultraviolet-wavelength pulse laser light UVL and the ultrashort pulse laser light UPL output from the laser light apparatus 100. The processor 150 controls the stage 370 to adjust the position of the glass substrate 20 in such a way that the desired position on the glass substrate 20 is irradiated with the ultraviolet-wavelength pulse laser light UVL and the ultrashort pulse laser light UPL output from the laser light apparatus 100.

The ultraviolet-wavelength pulse laser light source 400 is a gas laser apparatus that outputs excimer laser light, for example, a KrF excimer laser apparatus that outputs laser light having a center wavelength of about 246.0 nm, or an ArF excimer laser apparatus that outputs laser light having a center wavelength of about 193.4 nm. The ultraviolet-wavelength pulse laser light source 400 may be a YAG laser apparatus that outputs frequency-converted third harmonic light (having wavelength of about 355 nm) or fourth harmonic light (having wavelength of about 266 nm). The ultraviolet-wavelength pulse laser light source 400 is electrically connected to and controlled by the processor 150.

### 2.2 Description of Glass Substrate Processing Method

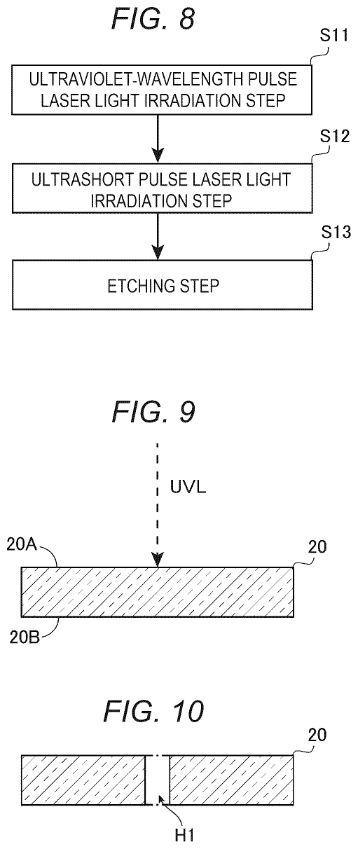

A glass substrate processing method according to the first embodiment will next be described with reference to FIGS. 8 to 14.

FIG. 8 is a flowchart showing the procedure of the glass substrate processing method according to the present embodiment. The glass substrate processing method according to the present embodiment includes steps S11 to S13, as shown in FIG. 8.

### <Step S11>

This step is an ultraviolet-wavelength pulse laser light irradiation step of irradiating the glass substrate 20 with the ultraviolet-wavelength pulse laser light UVL. FIG. 9 shows that the glass substrate 20 is irradiated with the ultraviolet-wavelength pulse laser light UVL. In this step, the processor 150 controls the ultraviolet-wavelength pulse laser light source 400 to cause it to output the ultraviolet-wavelength pulse laser light UVL, as shown in FIG. 7. The ultraviolet-wavelength pulse laser light UVL enters the radiation optical system 350 and is focused and radiated to a desired position on the glass substrate 20 located at a position adjusted by the stage 370. As a result of ablation caused by the laser light radiation, a hole is deeply cut into the glass substrate 20, and a through hole H1 is formed in the glass substrate 20, as shown in FIG. 10. It is preferable in the present embodiment that the hole diameter of the formed through hole H1 is greater than or equal to 5 μm but smaller than or equal to 100 μm. The hole diameter of the through hole H1 may instead be smaller than 5 μm or greater than 100 μm. After this step, step S12 is executed.

### <Step S12>

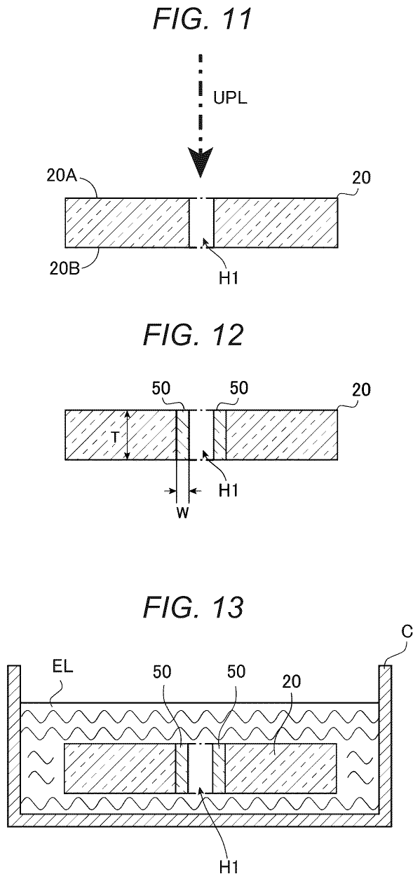

This step is an ultrashort pulse laser light irradiation step of irradiating the glass substrate 20 with the ultrashort pulse laser light UPL. FIG. 11 shows that a region surrounding the through hole H1 and extending over a predetermined range from an inner wall of the through hole H1 is irradiated with the ultrashort pulse laser light UPL. In this step, the processor 150 first controls the stage 370 to cause it to move the glass substrate 20 from the position indicated by the dotted line in FIG. 7 and irradiated with the ultraviolet-wavelength pulse laser light UVL to the position indicated by the solid line in FIG. 7 to be irradiated with the ultrashort pulse laser light UPL. The processor 150 then controls the ultrashort pulse laser light source 130 to cause it to output the ultrashort pulse laser light UPL. The ultrashort pulse laser light UPL enters the radiation optical system 310. The ultrashort pulse laser light UPL is radiated to the desired position on the glass substrate 20 located at the position adjusted by the stage 370. At this point in time, the processor 150 controls the focus position adjuster 330 to cause it to bring the ultrashort pulse laser light UPL into focus at the desired position. The processor 150 controls the focus position adjuster 330 to cause it to move the position where the ultrashort pulse laser light UPL is brought into focus, for example, from the one surface 20A to the other surface 20B. As a result of the focus position movement, the glass substrate 20 in the region surrounding the through hole H1 and extending over the predetermined range from the inner wall of the through hole H1 is modified, so that the modified section 50 is formed, as shown in FIG. 12. Now, let T be the thickness of the glass substrate 20, and W be the thickness of the modified section 50 surrounding the through hole H1, and it is preferable that Expression (3) below is satisfied.

$$W < T / 2 \qquad ( 3 )$$

Note that the processor 150 may cause the focus position adjuster 330 to move the position where the ultrashort pulse laser light UPL is brought into focus in the thickness direction from the other surface 20B to the one surface 20A of the glass substrate 20 to grow the modified section 50 in the thickness direction, or may change the laser light focused position in another predetermined process.

In the laser processing system 10 according to the present embodiment, the ultraviolet-wavelength pulse laser light UVL and the ultrashort pulse laser light UPL are radiated to the region surrounding the through hole H1 and extending over the predetermined range from the inner wall of the through hole H1. The center axis of the through hole H1 and the center axis of the modified section 50 formed in a cylindrical shape therefore substantially coincide with each other. When the center axis of the modified section 50 and the center axis of the through hole H1 deviate from each other, the amount of deviation preferably falls, for example, within 10% the diameter of the modified section 50 in an XY plane. In the present embodiment, the outer diameter of the modified section 50 is greater than or equal to 20 μm but smaller than or equal to 200 μm. The amount of deviation between the center axis of the modified section 50 and the center axis of the through hole H1 is therefore desirably, for example, smaller than or equal to 2 μm. Note that the outer diameter of the modified section 50 may be smaller than 20 μm or greater than 200 μm. After this step, step S13 is executed.

### <Step S13>

This step is the step of etching the glass substrate 20 to increase the hole diameter of the through hole H1. FIG. 13 shows the etching steps of increasing the hole diameter of the through hole H1 in the present embodiment. In this step, the glass substrate 20 is immersed in the etchant EL stored in the container C, as shown in FIG. 13. The etchant EL provides the etching rate for etching the modified section 50 formed in step S12 higher than the etching rate for etching the glass substrate 20 excluding the modified section 50, as in Comparative Example. A ratio R of the etching rate at which the modified section 50 is etched to the etching rate at which the glass substrate 20 excluding the modified section 50 is etched is preferably greater than or equal to two. In the present embodiment, the etching rate at which the modified section 50 is etched is, for example, four times the etching rate at which the glass substrate 20 excluding the modified section 50 is etched. When Expression (3) described above is satisfied, the etching period for which the through hole H1 is enlarged may be shorter than that in Comparative Example.

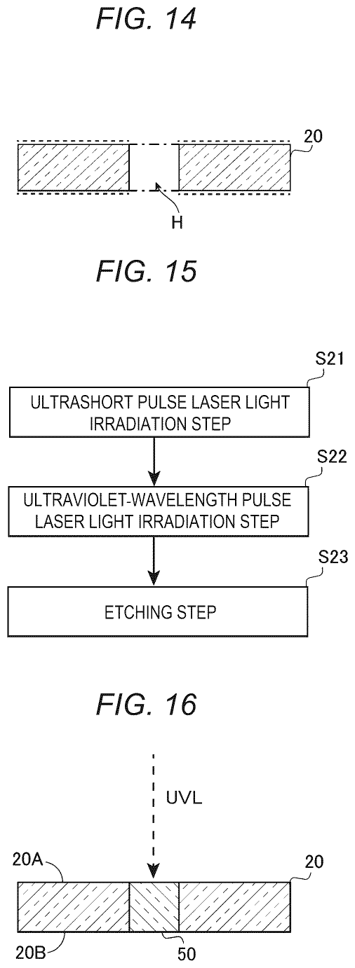

FIG. 14 shows the resultant glass substrate 20 processed by using the glass substrate processing method according to the present embodiment. In FIG. 14, the dotted lines indicate the glass substrate 20 before the processing. In the present embodiment, the inner diameter of the enlarged through hole H is, for example, greater than or equal to 20 μm but smaller than or equal to 200 μm. Comparison with FIG. 6 showing the result in Comparative Example shows that the amount of loss of the glass substrate 20 due to the etching for forming the through hole H is smaller in the present embodiment. Furthermore, since the etching proceeds from the entire region of the inner wall of the through hole H1, the formed through hole H is unlikely to have a curved inner wall, but has a substantially cylindrical shape, as shown in FIG. 14.

Let d2 be the hole diameter of the through hole H1 formed by the ultraviolet-wavelength pulse laser light UVL. In this case, the amount of etching EC₁ required to enlarge the through hole H1 to form the through hole H having the hole diameter d1 is expressed by Expression (4) below.

$${EC}_{1} = ( 1 / 2 ) \times ( d 1 - d 2 ) \qquad ( 4 )$$

The amount of reduction EL₁ in the plate thickness of the glass substrate 20 in the case of the amount of etching EC₁ is expressed by Expression (5) below.

$${EL}_{1} = 2 \times ( 1 / R ) \times {EC}_{1} \qquad ( 5 )$$

In Expression (5), R represents the etching rate ratio of the etching rate ESD, at which the modified section 50 is etched, to the etching rate ESN, at which the glass substrate 20 excluding the modified section 50 is etched, as in Comparative Example. Assume now, for example, that the plate thickness of the glass substrate 20 before processed is 1000 μm, as in Comparative Example, the hole diameter d1 of the through hole H is 60 μm, the hole diameter d2 of the through hole H1 is 20 μm, and R is 4. Then, the amount of etching EC₁ derived from Expression (4) is 20 μm, and the amount of reduction EL₁ in the plate thickness derived from Expression (5) is 10 μm. Since the amount of reduction EL₀ in the plate thickness caused by the etching of the glass substrate 20 in Comparative Example was 250 μm, the loss of the material in the present embodiment is 1/25 of that in Comparative Example. In addition, since the amount of etching EC₁ decreases, the etching period also advantageously shortens. In the aforementioned example of the present embodiment, the etching period is 1/25 of that in Comparative Example.

### 2.3 Effects and Advantages

In the glass substrate processing method according to the present embodiment, the etchant EL can enter the modified section 50 formed in the region extending over the predetermined range from the inner wall of the through hole H1 formed in advance, so that the etched area can increase, and the etching period for which the hole diameter of the through hole H1 is increased can shorten. An increase in the loss of the material due to the etching for enlarging the through hole H1 can therefore be suppressed.

In the glass substrate processing method according to the present embodiment, the deviation between the center axis of the through hole H1 formed by the ultraviolet-wavelength pulse laser light UVL and the center axis of the modified section 50 formed by the ultrashort pulse laser light UPL is 2 μm or smaller. Variation in the thickness of the modified section 50 formed in the region extending over the predetermined range from the inner wall of the through hole H1 can therefore be suppressed. The etching period for which the hole diameter of the through hole H1 is increased can therefore be further shortened. The reduction in the thickness of the glass substrate 20 due to the etching can therefore be further suppressed.

In the laser processing system 10 according to the present embodiment, the processor 150 controls the focus position adjuster 330 to cause it to move the position where the ultrashort pulse laser light UPL is brought into focus in the thickness direction, and a conical lens may instead be used to convert the ultrashort pulse laser light UPL into a Bessel beam. The Bessel beam is non-diffracted light and propagates without spreading with the focused state maintained. The cylindrical modified section 50 can therefore be formed with the position where the ultrashort pulse laser light UPL is brought into focus fixed in the thickness direction relative to the glass substrate 20.

### 3. Description of Laser Processing System and Glass Substrate Processing Method According to Second Embodiment

The laser processing system according to a second embodiment will next be described. Note that the same configurations as those described above have the same reference characters, and duplicate description of the same configurations will be omitted unless otherwise particularly described.

### 3.1 Configuration of Laser Processing System

The laser processing system 10 according to the present embodiment is the same as that according to the first embodiment described above, and will therefore not be described.

### 3.2 Description of Glass Substrate Processing Method

A glass substrate processing method according to the second embodiment will next be described with reference to FIGS. 3, 4, 7, and 12 to 16.

FIG. 15 is a flowchart showing the procedure of the glass substrate processing method according to the present embodiment. The glass substrate processing method according to the present embodiment includes steps S21 to S23, as shown in FIG. 15. The flowchart in FIG. 15 differs from the flowchart of FIG. 8 in the first embodiment in that the ultrashort pulse laser light irradiation step and the ultraviolet-wavelength pulse laser light irradiation step are swapped.

### <Step S21>

This step is an ultrashort pulse laser light irradiation step of irradiating the glass substrate 20 with the ultrashort pulse laser light UPL. This step is the same as the step S1 of Comparative Example, and will therefore not be described. In this step, as a result of the ultrashort pulse laser light irradiation, the cylindrical modified section 50 is formed in the glass substrate 20, as in FIG. 4. Note in the present embodiment that the outer diameter of the modified section 50 is preferably greater than or equal to 20 μm but smaller than or equal to 200 μm. The outer diameter of the modified section 50 may instead be smaller than 20 μm or greater than 200 μm. After this step, step S22 is executed.

### <Step S22>

This step is an ultraviolet-wavelength pulse laser light irradiation step of irradiating the glass substrate 20 with the ultraviolet-wavelength pulse laser light UVL. FIG. 16 shows that the modified section 50 formed in the glass substrate 20 is irradiated with the ultraviolet-wavelength pulse laser light UVL. In this step, the processor 150 controls the ultraviolet-wavelength pulse laser light source 400 to cause it to output the ultraviolet-wavelength pulse laser light UVL. The ultraviolet-wavelength pulse laser light UVL enters the radiation optical system 350. The ultraviolet-wavelength pulse laser light UVL is focused and radiated to a desired position on the glass substrate 20 the position of which has been adjusted by the stage 370. In the present embodiment, the ultraviolet-wavelength pulse laser light UVL is radiated to the center axis of the modified section 50 formed in a cylindrical shape in the glass substrate 20 and to a portion in the vicinity of the center axis. As a result of ablation caused by the laser light radiation, a hole is deeply cut into the glass substrate 20, and the through hole H1 is formed in the glass substrate 20, as shown in FIG. 12. It is preferable in the present embodiment that the hole diameter of the formed through hole H1 is greater than or equal to 5 μm but smaller than or equal to 100 μm. The hole diameter of the through hole H1 may instead be smaller than 5 μm or greater than 100 μm.

In the laser processing system 10 according to the present embodiment, the ultraviolet-wavelength pulse laser light UVL is radiated to the center axis of the modified section 50 formed in a cylindrical shape in the glass substrate 20 and to a portion in the vicinity of the center axis. The center axis of the through hole H1 and the center axis of the modified section 50 formed in a cylindrical shape therefore substantially coincide with each other. When the center axis of the modified section 50 and the center axis of the through hole H1 deviate from each other, the amount of deviation preferably falls, for example, within 10% the outer diameter of the modified section 50 in an XY plane. In the present embodiment, the outer diameter of the modified section 50 is greater than or equal to 20 μm but smaller than or equal to 200 μm. The amount of deviation between the center axis of the modified section 50 and the center axis of the through hole H1 is therefore desirably, for example, smaller than or equal to 2 μm. The amount of deviation between the center axis of the modified section 50 and the center axis of the through hole H1 may instead be greater than 2 μm. Furthermore, the outer diameter of the modified section 50 may be smaller than 20 μm or greater than 200 μm. After this step, step S23 is executed. Also in the present embodiment, it is preferable that Expression (3) described above is satisfied.

### <Step S23>

This step is the step of etching the glass substrate 20 to increase the hole diameter of the through hole H1. FIG. 13 shows the etching steps of increasing the hole diameter of the through hole H1 in the present embodiment. In this step, the glass substrate 20 is immersed in the etchant EL stored in the container C, as shown in FIG. 13, as in step 13 in the first embodiment. The etchant EL provides the etching rate for the modified section 50 formed in step S21 higher than the etching rate for the glass substrate 20 excluding the modified section 50, as in the first embodiment. A ratio R of the etching rate at which the modified section 50 is etched to the etching rate at which the glass substrate 20 excluding the modified section 50 is etched is preferably greater than or equal to two. In the present embodiment, the etching rate at which the modified section 50 is etched is, for example, four times the etching rate at which the glass substrate 20 excluding the modified section 50 is etched. Comparison between the etching of the modified section 50 in the thickness direction and the etching of the modified section 50 in the direction in which the hole diameter of the through hole H1 is increased shows that the etching period for which the through hole H1 is enlarged may be shorter than in Comparative Example described above when Expression (3) is satisfied.

The result of the etching described in aforementioned step S23 is the same as the result in FIG. 14, which describes the result of the etching of the glass substrate 20 processed by using the glass substrate processing method according to the first embodiment.

In FIG. 14, the dotted lines indicate the glass substrate 20 before the processing. In the present embodiment, the inner diameter of the enlarged through hole H is, for example, greater than or equal to 20 μm but smaller than or equal to 200 μm. Comparison with FIG. 6 showing the result in Comparative Example shows that the amount of loss of the glass substrate 20 due to the etching for enlarging the through hole H1 is smaller in the present embodiment. Furthermore, since the etching proceeds from the entire region of the inner wall of the through hole H1, the enlarged through hole H is unlikely to have a curved inner wall, but has a substantially cylindrical shape, as shown in FIG. 14.

### 3.3 Effects and Advantages

In the glass substrate processing method according to the present embodiment, the etchant EL can enter the modified section 50 formed in the region extending over the predetermined range from the inner wall of the through hole H1 formed in advance, so that the etched area increases, and the etching period for which the through hole H having a target hole diameter is formed can shorten, as in the first embodiment. An increase in the loss of the material due to the etching for enlarging the through hole H1 can therefore be suppressed.

### 4. Description of Electronic Device Manufacturing Method According to Third Embodiment

### 4.1 Configuration

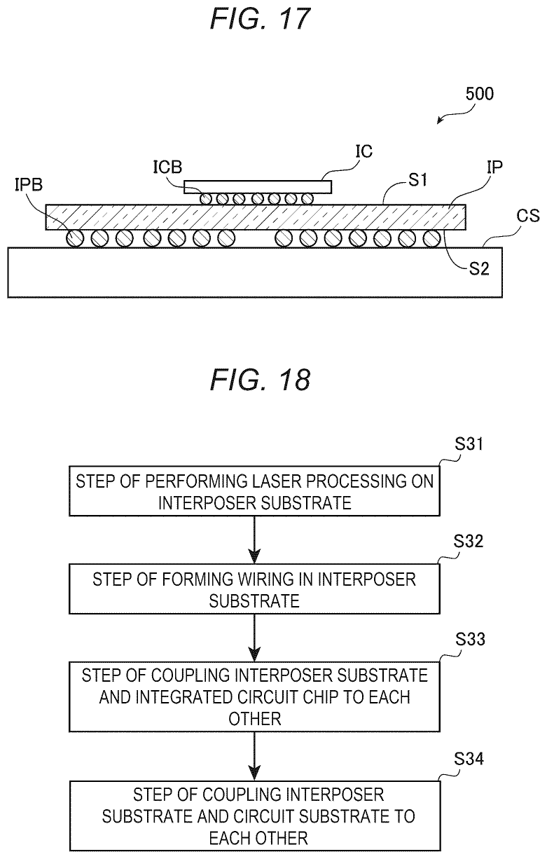

FIG. 17 diagrammatically shows the configuration of an electronic device manufactured in accordance with the present embodiment. An electronic device 500 includes an integrated circuit chip IC, an interposer substrate IP, and a circuit substrate CS. The integrated circuit chip IC is, for example, a chip configured with a silicon substrate in which an integrated circuit that is not shown is formed. The integrated circuit chip IC is provided with multiple bumps ICB electrically connected to the integrated circuit. The interposer substrate IP is an insulating glass substrate 20 having multiple through holes H, which are not shown in FIG. 17 but are formed therein, and an electric conductor E, which electrically connects the front and rear sides of the glass substrate 20 to each other, is provided in each of the through holes H. The through holes H are formed by using the glass substrate processing method described in the first or second embodiment. The multiple bumps ICB, which are metal connection protrusions, and multiple lands that are metal contacts that are not shown but are connected to the respective bumps ICB are formed at one surface of the interposer substrate IP, and the lands are each electrically connected to one of the electric conductors E in the through holes H. Multiple bumps IPB are provided at the other surface of the interposer substrate IP, and the bumps IPB are each electrically connected to one of the electric conductors E in the through holes H. Multiple lands that are not shown but are connected to the respective bumps IPB, which are metal connection protrusions, are formed at one surface of the circuit substrate CS. The circuit substrate CS includes multiple terminals to be electrically connected to the respective lands.

### 4.2 Description of Electronic Device Manufacturing Method

An electronic device manufacturing method according to a third embodiment will next be described with reference to FIGS. 17 to 19. FIG. 18 is a flowchart showing the procedure of the electronic device manufacturing method according to the present embodiment. The present embodiment includes steps S31 to S34, as shown in FIG. 18.

### <Step S31>

This step is the step of performing laser processing on the interposer substrate IP, that is, the step of forming the through holes H in the interposer substrate IP manufactured by the glass substrate 20. The through holes H are formed by using the glass substrate processing method described in the first or second embodiment described above. After this step, step S32 is executed.

### <Step S32>

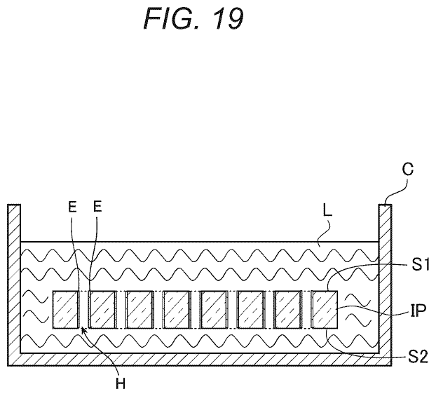

This step is the step of forming wiring in the interposer substrate IP, that is, the step of forming the electric conductors E, which electrically connect the two principal surfaces of the interposer substrate IP to each other, in the through holes H in the interposer substrate IP. FIG. 19 diagrammatically shows the wiring formation step of placing the electric conductors E in the through holes H in the interposer substrate IP. In this step, for example, electroplating using an electrolyte L is used to deposit metal, for example, copper at the inner wall of each of the through holes H as shown in FIG. 19, so that a first principal surface S1 and a second principal surface S2 are electrically connected to each other. The electric conductors E may, of course, be formed by using electroless plating or any other method. The lands are formed so as to overlap with circumferential edge portions of the openings of the through holes H, in which the electric conductors E are embedded. The lands may be formed simultaneously with the step of forming the electric conductors E, or may be formed in another step. After this step, step S33 is executed.

### <Step S33>

This step is a coupling step of coupling the interposer substrate IP and the integrated circuit chip IC to each other. In this step, the bumps ICB of the integrated circuit chip IC are brought into contact with the lands of the interposer substrate IP, so that the bumps ICB and the lands are electrically connected to each other. After this step, step S34 is executed.

### <Step S34>

This step is a coupling step of coupling the interposer substrate IP and the circuit substrate CS to each other. In this step, the bumps IPB of the interposer substrate IP are placed on the lands of the circuit substrate CS, so that the bumps IPB and the lands are electrically connected to each other. As a result of this step, the electronic device 500 is manufactured as shown in FIG. 17.

The processor 150 may be physically configured as hardware to execute the various processes included in the present disclosure. For example, the processor 150 may be a computer including a memory that stores a control program defining the various processes and a processing device that executes the control program. The control program may be stored in one memory, or may be stored separately in a plurality of memories at physically separate locations, and the various processes included in the present disclosure may be defined by a combination of control programs stored in the memories. The processing device may be a general-purpose processing device such as a CPU or a special-purpose processing device such as a GPU. Alternatively, the processor 150 may be programmed as software to execute the various processes included in the present disclosure. For example, the processor 150 may be implemented in a dedicated device such as an ASIC or a programmable device such as a FPGA. The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined. The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A glass substrate processing method comprising:
forming a through hole by irradiating a glass substrate with ultraviolet-wavelength pulse laser light;
forming a modified section by irradiating a region surrounding the through hole with ultrashort pulse laser light, the region extending over a predetermined range from an inner wall of the through hole; and
etching the glass substrate with an etchant to increase a hole diameter of the through hole, the etchant providing an etching rate for etching the modified section higher than an etching rate for etching the glass substrate excluding the modified section.

2. The glass substrate processing method according to claim 1, wherein
an expression below is satisfied,
$$W < T / 2$$
where W represents a thickness of the modified section, and T represents a thickness of the glass substrate.

3. The glass substrate processing method according to claim 1, wherein
a center axis of the modified section and a center axis of the through hole deviate from each other by 2 μm or smaller.

4. The glass substrate processing method according to claim 1, wherein
the ultraviolet-wavelength pulse laser light is a KrF excimer laser light.

5. The glass substrate processing method according to claim 1, wherein
the ultrashort pulse laser light is a Bessel beam.

6. The glass substrate processing method according to claim 1, wherein
a wavelength of the ultrashort pulse laser light has a 1-μm band.

7. The glass substrate processing method according to claim 1, wherein
a thickness of the glass substrate is greater than or equal to 100 μm but smaller than or equal to 2000 μm, and
a hole diameter of the through hole formed by the radiation of the ultraviolet-wavelength pulse laser light is greater than or equal to 5 μm but smaller than or equal to 100 μm.

8. The glass substrate processing method according to claim 1, wherein
the increased hole diameter of the through hole is greater than or equal to 20 μm but smaller than or equal to 200 μm.

9. The glass substrate processing method according to claim 1, wherein
the modified section has a cylindrical shape.

10. A glass substrate processing method comprising:
forming a modified section by irradiating a glass substrate with ultrashort pulse laser light,
forming a through hole surrounded by the modified section by irradiating the glass substrate with ultraviolet-wavelength pulse laser light; and
etching the glass substrate with an etchant to increase a hole diameter of the through hole, the etchant providing an etching rate for etching the modified section higher than an etching rate for etching the glass substrate excluding the modified section.

11. The glass substrate processing method according to claim 10, wherein
an expression below is satisfied,
$$W < T / 2$$
where W represents a thickness of the modified section after the through hole is formed, and T represents a thickness of the glass substrate.

12. The glass substrate processing method according to claim 10, wherein
a center axis of the modified section and a center axis of the through hole deviate from each other by 2 μm or smaller.

13. The glass substrate processing method according to claim 10, wherein
the ultraviolet-wavelength pulse laser light is a KrF excimer laser light.

14. The glass substrate processing method according to claim 10, wherein
the ultrashort pulse laser light is a Bessel beam.

15. The glass substrate processing method according to claim 10, wherein
a wavelength of the ultrashort pulse laser light has a 1-μm band.

16. The glass substrate processing method according to claim 10, wherein
a thickness of the glass substrate is greater than or equal to 100 μm but smaller than or equal to 2000 μm, and
a hole diameter of the through hole formed by the radiation of the ultraviolet-wavelength pulse laser light is greater than or equal to 5 μm but smaller than or equal to 100 μm.

17. The glass substrate processing method according to claim 10, wherein
the increased hole diameter of the through hole is greater than or equal to 20 μm but smaller than or equal to 200 μm.

18. The glass substrate processing method according to claim 10, wherein
the modified section before the through hole is formed has a cylindrical shape.

19. An electronic device manufacturing method comprising:
forming a through hole by irradiating a glass substrate with ultraviolet-wavelength pulse laser light;
forming a modified section by irradiating a region surrounding the through hole with ultrashort pulse laser light, the region extending over a predetermined range from an inner wall of the through hole;
etching the glass substrate with an etchant to increase a hole diameter of the through hole, the etchant providing an etching rate for etching the modified section higher than an etching rate for etching the glass substrate excluding the modified section, to produce an interposer substrate;
placing an electric conductor in the through hole having the increased hole diameter in the interposer substrate, and electrically connecting two principal surfaces of the interposer substrate to each other via the electric conductor;
coupling the interposer substrate and an integrated circuit chip to each other to electrically connect the interposer substrate and the integrated circuit chip to each other; and
coupling the interposer substrate and a circuit substrate to each other to electrically connect the interposer substrate and the circuit substrate to each other.
